(19) United States
(12) Patent Application Publication
(10) Pub. No.: US 2002/0136418 A1
(43) Pub. Date: Sep. 26, 2002

(54) High efficiency regenerative piezoelectric drive amplifier

(76) Inventors: Wayne M. Zavis, Clarksville, MD (US); Wayne E. Shanks, (US)

Correspondence Address: BLANK ROME COMISKY & MCCAULEY LLP, THE FARRAGUT BUILDING, SUITE 1000, 900 17th STREET, NW, WASHINGTON, DC, 20006, US

(21) Appl. No.: 09/885,919

(22) Filed: Jun. 22, 2001

Related U.S. Application Data
(60) Provisional application No. 60/213,640, filed on Jun. 23, 2000.

(51) Int. Cl. H04R 3/00; H03F 21/00

(52) U.S. Cl. 381/114; 381/120; 381/173; 381/174

(57) ABSTRACT

The present circuit is for a resonant, regenerative switching piezomotor drive amplifier that efficiently converts electrical energy into mechanical work through a piezoelectric actuator. The actuator driver of the present invention drives the real work-producing part of the system load over a broad range of frequencies from DC to several kHz, dramatically increasing the system power efficiency and full power bandwidth. The gains in efficiency are obtained by operating the motor/amplifier system at both electrical and mechanical resonances for the system. The amplifier's efficiency is greater than 80% when driving a 1 μF piezoelectric load with a 500 V peak-to-peak signal. The available output power is greater than 20 watts continuously from DC to 2.0 kHz.

The resonant, switching regenerative piezomotor drive amplifier described herein not only drives high voltage piezoelectric actuators, but will also serve equally well in any application that requires high power drive signals to be applied to a predominantly capacitive load.

### REFERENCE TO RELATED APPLICATION

This application is based upon and claims priority of a provisional application, Serial No. 60/213,640 filed on Jun. 23, 2000, the full disclosure of which is incorporated by reference herein.

### FIELD OF INVENTION

The present invention is directed toward a resonant, regenerative switching drive amplifier that efficiently converts electrical energy into mechanical work through a piezoelectric actuator, and operates at both electrical and mechanical resonances for a motor/amplifier system.

### BACKGROUND OF THE INVENTION

Piezoelectric actuators differ from electromagnetic actuators in the load they present and mode by which they do work. Piezoelectric actuators produce very large forces, but over micron displacements. Useful work can only be extracted by accumulating the small stroke of the actuator at high frequencies. Since the actuator displacements are small and at high frequencies, the inertia and compliance of the mechanical accumulator must be taken into consideration. On every stroke of the actuator, energy is delivered to the mechanical load and deposited in the spring-like compliance of the actuator. The system's mass and compliance form a mechanical resonant system, and energy not delivered to load or recovered from the system is lost as heat. This results in mechanical impedance of the actuator and load system. The portion of the load that does useful work has real impedance, and the portion of the load that stores energy in compression and momentum has an imaginary impedance. By driving the system at its natural compression and momentum has an imaginary impedance. By driving the system at its natural mechanical resonance, the imaginary component of the mechanical impedance is canceled, leaving just the real component that does useful work.

Piezoelectric actuators also present a very large capacitive load. The first order electrical model for a piezoelectric actuator is a capacitor in series with a resistor. The resistor in the model represents the work-producing part of the mechanical load. Like the mechanical system, the load capacitance can be resonated to leave just the real part of the load. However, practical considerations often (1) prevent the coincidence of electrical and mechanical resonances and (2) dictate that the actuator be driven over a wide band of frequencies.

It should be noted that several methods for resonant piezoelectric drivers are patented (U.S. Pat. Nos. 5,126,589, 4,109,174, and 4,767,959), but they are impractical because of difficulties associated with floating drive signals, inefficient diodes, BJT transistors, or SCRs. Diodes, BJT, and SCRs have a minimum forward voltage across their semiconductor junctions, thus they represent large V*I power losses.

### SUMMARY OF THE INVENTION

Piezoelectric actuators and motors deliver useful work at power densities an order of magnitude greater than that of their electromagnetic counterparts. With this in mind, the present circuit is for a resonant, regenerative switching piezomotor drive amplifier that efficiently converts electrical energy into mechanical work through a piezoelectric actuator.

The Resonant Regenerative Switching Amplifier combines the wide bandwidth and flexibility of a linear power amplifier with the high efficiency of a driven tank circuit. In a linear amplifier, high current is repeatedly sourced and then sunk when driving a capacitive load. On each cycle, the capacitor is loaded with energy and then this energy is discarded. At low to moderate frequencies, this wasted reactive power can be substantially larger than the power delivered to the work-producing part of the load, thus causing very low system energy efficiency.

The actuator driver of the present invention is able to drive the real work-producing part of the system load over a broad range of frequencies from DC to several kHz, dramatically increasing the system power efficiency and full power bandwidth. The gains in efficiency are obtained by operating (transferring and converting the energy) the motor/amplifier system at both electrical and mechanical resonances for the system. The amplifier's efficiency is greater than 80% when driving a 1 μF piezoelectric load with a 500 V peak-to-peak signal. The available output power is greater than 20 watts continuously from DC to 2.0 kHz.

The resonant, switching regenerative piezomotor drive amplifier described herein not only drive high voltage piezoelectric actuators, but will also serve equally well in any application that requires high power drive signals to be applied to a predominantly capacitive load.

An article describing the present invention, entitled DESIGN ADVANCES FOR HIGH-EFFICIENCY REGENERATIVE PIEZOELECTRIC DRIVE AMPLIFIER, Proceeding of SPIE, Smart Structures and Materials, March 2001, written by Wayne Zavis and Wayne Shanks is incorporated herein by reference.

### BRIEF DESCRIPTION OF THE DRAWINGS

FIG. 1 is a graph showing the efficiency of different Piezoelectric Drive systems based on the amplifier used and the frequency of an input signal;

FIG. 2 is a graph showing the piecewise approximation of the mechanical resonance by the electric resonance;

FIG. 3 shows a circuit diagram of a basic piezoelectric drive amplifier of the present invention;

FIG. 4 shows transfer of energy from the storage capacitor to the piezoelectric element of FIG. 3;

FIG. 5 shows a circuit diagram of the piezoelectric drive amplifier of the present invention incorporated into a power handling system; and

FIG. 6 shows a picture of the piezoelectric motor mated with a drive amplifier.

### DETAILED DESCRIPTION OF THE INVENTION

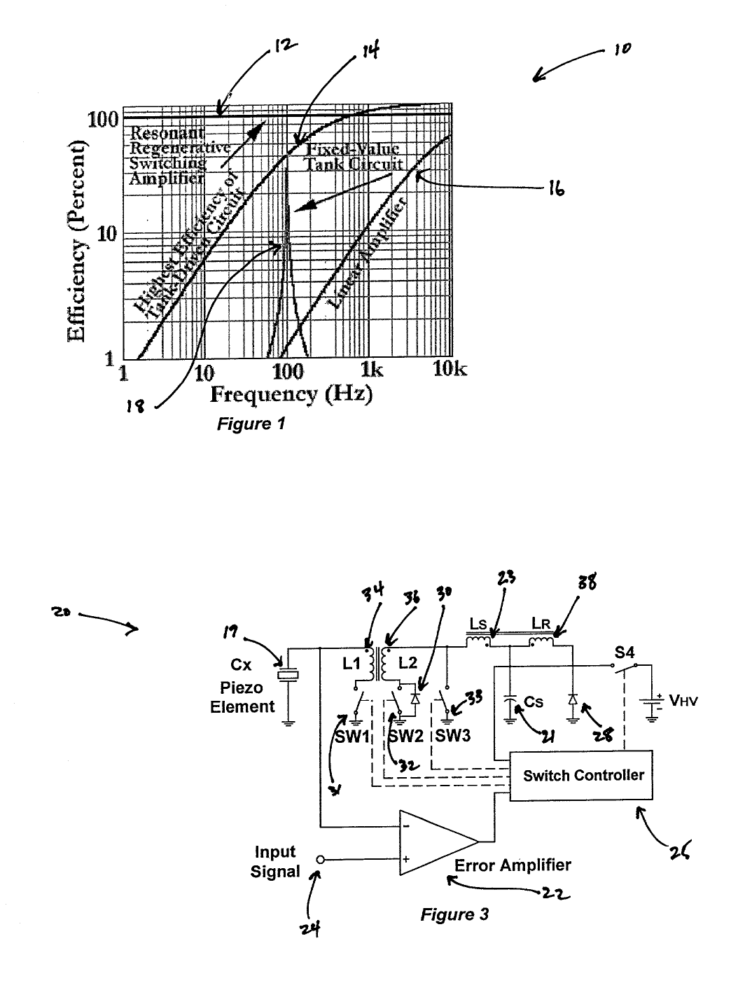

Referring now to the drawings, a preferred embodiment is described where like elements are designated by like elements numbers. FIG. 1 shows a chart 10 comparing the efficiency of a piezo-driver system using various drive amplifiers for a range of input frequencies. The chart 10 shows that the efficiency for a circuit using the resonant regenerative switching amplifier 12 of the present invention provides high efficiency at low frequencies. The tank driven circuit 14 and the linear amplifier circuit 16 have efficiencies which increase as the frequency increases, and the fixed-value tank circuit 18 has a narrow and limited band of frequencies where the efficiency of the circuit peaks.

The wasteful reactive component of the impedance can be canceled by adding a conjugate inductance, leaving the load a pure resistance. Electrically this only occurs at one frequency, the resonant frequency of the inductor-resistor-capacitor or LRC (tank) system. The efficiency of this tank circuit can be explained by realizing that the energy stored on the capacitor is not thrown away, but transferred to the inductor and then transferred back to the capacitor every cycle. External power need only provide what is lost to mechanical work and resistive heating. The most efficient conversion of electrical energy to mechanical work will thus occur only at the narrow band of frequencies around electrical resonance. To make available a larger band of frequencies, the inductor value must be dynamically adjusted to change the resonant frequency. Since dynamically adjustable power inductors are currently impractical, the high-efficiency operation of the system is severely band limited.

This problem of narrow-band operation can be overcome if temporary energy storage is accomplished not in the inductor, but another capacitor. Analogous to water tanks, energy can be resonantly transferred between two capacitors, the load piezoelectric element and a storage capacitor, without dissipating appreciable power. Unlike energy stored in an inductor, the back and forth transfer of energy in two capacitors can stop for an arbitrary period and then resume with little loss of energy. By transferring small bursts of energy at high frequencies, the voltage on the piezoelectric element can be ramped up or down in a piece-wise approximation to any arbitrary waveform, as shown in FIG. 2. In this way, the electric resonance can be made to match the mechanical resonance of the system. With this technique, the driver can operate with high efficiency at frequencies from direct current (DC) all the way to some limiting frequency below the energy-transfer resonance. Present switching technology puts this upper frequency limit at several kHz, but tradeoffs in signal distortion and power efficiency can raise or lower this upper bound.

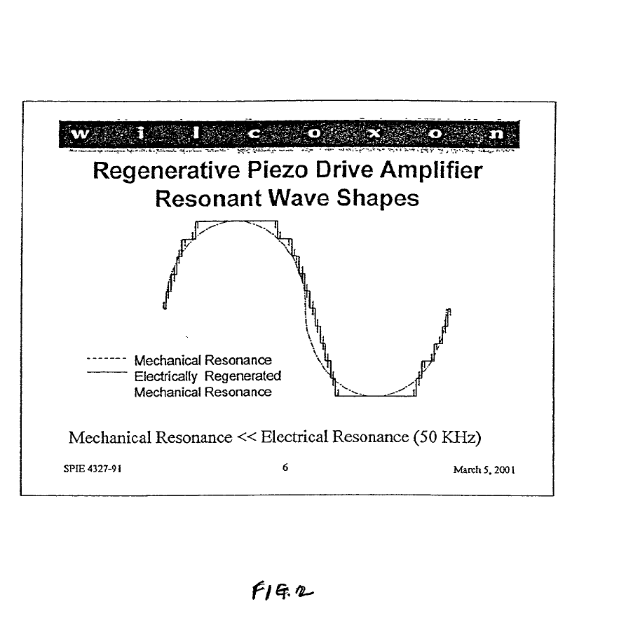

FIG. 3 shows a circuit 20 of the preferred embodiment using the resonant regenerative switching amplifier which allows high efficiency at low frequencies. The process of moving stored energy from one capacitor to the other, and vice versa is described herein, where the first capacitor is a piezoelectric element 19 having a capacitance Cx and the second capacitor is a storage capacitor 21 having a capacitance Cs. For the purposes of this description, consider that the capacitance Cs of the storage capacitor 21 starts out charged to the system's maximum potential (Vₘₐₓ) and the capacitance Cx of the piezoelectric element 19 is at a 0 volt potential. All potentials are always positive, and the piezoelectric element 19 and the storage capacitor 21 are equal-valued capacitors. The circuit 20 is designed to piece-wise approximate on the piezoelectric element 19 an arbitrary waveform seen at an input (V_{IN}) of an error amplifier 22. At time zero, both the voltage (V_{cx}) on the piezoelectric element 19 and an input signal 24 start at 0 V.

The operation of this switching system can be considered in two categories of energy transfer, (1) the transfer of energy from the storage capacitor 21 to the piezoelectric element 19 and, (2) the transfer of energy from the piezoelectric element 19 to the storage capacitor 21. The storage capacitor to piezoelectric element sequence is shown in FIG. 3, which increases the voltage (V_{cx}) on the piezoelectric element 19. This is initiated by the error amplifier 22 when (V_{IN}-V_{cx})>αΔV, where ΔV is voltage step size, and α is a constant (0<α<1). When this condition is met, a current pre-load sequence is started in the switching controller 25 by closing a third switch 33. A current pre-load before the actual energy transfer is needed because during the transfer of energy from storage capacitor 21 to the piezoelectric element 19, the system is a freely oscillating inductor-capacitor (LC) system with a positive slope on V_{cx} and an instantaneous current present in the inductor 23. Since these boundary conditions of voltage and current are not present in the system during its hold state, where all the energy resides on one of the two capacitors, for a given V_{cx} some portion of the energy in the storage capacitor 21 must be transferred into the inductor 23. The initial conditions needed to transfer energy into piezoelectric element 19 are:

\sqrt{V_{css}²+V_{cx}²}−V_{cx}≧V_{cs}

In the equation above, V_{css} is the voltage on storage capacitor 21 before the third switch is closed, V_{cx} is the voltage on the piezoelectric element 19, and V_{cs} is the dropping voltage on the storage capacitor 21. When the boundary conditions are met, the transfer of energy is started by opening the third switch 33 and closing the first and second switches, 31 and 32. Inductors 34 and 36 transformer couple piezoelectric element 19 into storage capacitor 21 through inductor 23 to form a freely oscillating inductor-capacitor (LC) system. Assuming there is sufficient energy contained in the storage capacitor 21 for the transfer, V_{cx} increases until (VCX-V_{IN})>(1-α)ΔV. The transfer is terminated by the opening of the first and second switches, 31 and 32. For most steps there will be some energy remaining in inductor 23 at the termination of the transfer. This energy is recovered through a diode 26 connected between an inductor 38 and a ground 28. Most of the time the diode 26 is reverse biased, thus preventing the storage capacitor 21 from discharging through the inductor 38. During the inductor energy recovery phase, the collapsing field in the common core of the inductors, 23 and 38, forward bias the diode 26 and current flows into the storage capacitor 21, thus recovering nearly all the unused energy. The term “nearly all” is used since there is a 0.7V forward-voltage drop in the diode 26. This voltage, times the current through the diode 26, constitutes a loss that results in heating of the diode 26. The system now enters a hold phase until the next transfer event starts.

The other switching event is the transfer of energy from the piezoelectric element 19 to the storage capacitor 21. This is initiated by the error amplifier 22 when (V_{cx}-V_{IN})>αΔV. When this condition is met, the first switch 31 is closed and the piezoelectric element 19 starts to discharge through the inductor 34. If the potential on the storage capacitor 21 permits, the diode 30 on the second switch 32 is' forward biased; thus the piezoelectric element 19 and the storage capacitor 21 are transformer coupled through the inductor 23. The transfer proceeds until (V_{IN}-V_{cx})>(1-α)ΔV, at which point the first switch 31 is opened. If V_{cs} is too large to allow the diode 30 on the second switch 32 to forward bias when the first switch 31 is closed, then when the first switch 31 is opened the rapidly collapsing field in the core of the inductor 36 will forward bias the diode 30 and the energy will be transferred into the storage capacitor 21.

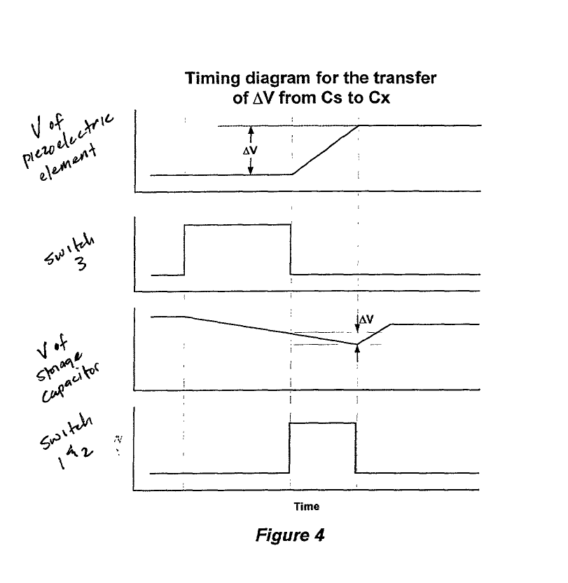

FIG. 4 shows the timing diagram of the change in the charge on the piezoelectric element and the storage capacitor in relation to the switches 31-33.

It is also possible to use variable energy stepsizes (ΔV≠constant) to piecewise reconstruct the mechanical resonance or input wave shapes. For example, applications driven by lower distortion requirements must make a tradeoff between distortion and bandwidth or another parameter to use variable step size to optimize their piezomotor/amplifier system performance.

In another embodiment of the invention, low on-resistance field effect transistor (FET) switches can be used to ensure that very little energy is lost to resistive heat. With a slight addition in circuit complexity, the diodes 26 and 30 described above can be replaced with FET synchronous rectifiers that have an added bias component. These FET switches behave like ideal diodes, and thus they dissipate very little energy when they conduct current. The circuit losses may be low, but they are non-zero. In addition, the piezoelectric element 19 is dissipating energy in the form of performed and delivered mechanical work. At some point energy must be added to the system. This is accomplished by periodically charging the storage capacitor 21 to a voltage that corresponds to the largest possible energy transfer from the storage capacitor 21 to the piezoelectric element 19. For a system with an energy step at the top of the voltage range, from 475V to 500V, the storage capacitor 19 requires approximately 160V. If the storage capacitor 19 is ever below this potential, it is quickly charged to slightly greater then 160V, thus always providing enough energy to make 25V increments all the way up to 500V. Since 160V represents the energy increment needed for one ΔV of 25V at approximately 500V, the maximum voltage on the storage capacitor 21 is 525V.

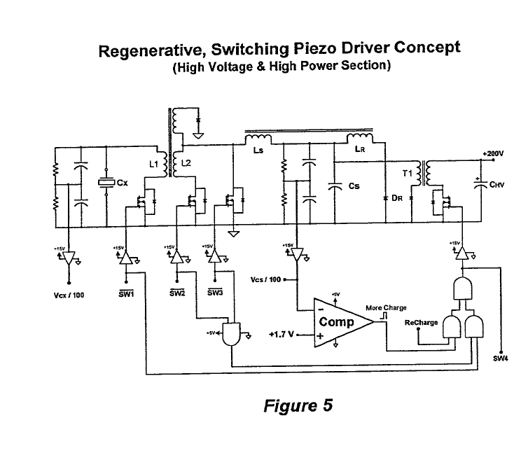

FIG. 5 shows the circuitry for a power handling system using the resonant, regenerative switching piezomotor drive amplifier technology. The circuit shown minimizes all power losses while dealing with the shortcomings of available circuit components. In this circuit high voltage, high speed, N-channel MOSFETs are used.

The system operates by chopping portions of the undriven inductor-capacitor (LC) resonance into discrete voltage steps at the actuator. The energy losses in the circuit come from resistive heating of the FET switches and other passive components. The FETs used have an on-resistance of 0.2 ohms and dominate the losses of the system.

Total system equivalent resistance is of the order of 1 ohm. Therefore, most of the energy moving around within the system is delivered to the load with a real load resistance as low as 10 ohms. A second feature of the chosen circuit topology is the use of ground referenced N-channel MOSFETs. This feature greatly simplifies the circuit operation. None of the control voltages needs to be floated at high voltage. Highly efficient “over the counter” gate driver integrated circuits (ICs) are used, keeping the switching transition time below 200 ns.

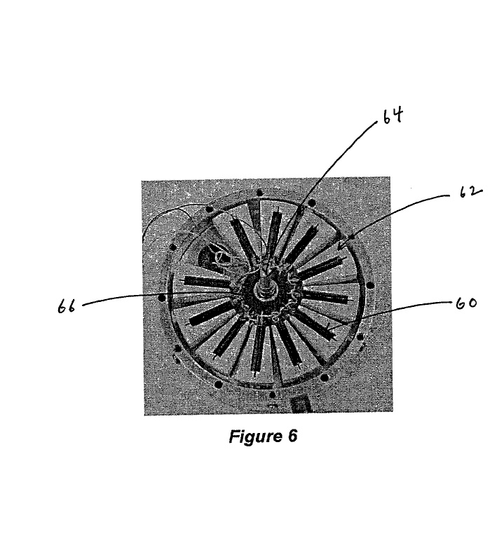

An example of an application for the resonant, regenerative switching piezomotor technology is to use the drive amplifier to power a miniature 12-beam piezomotor, shown in FIG. 6. The electromechanical performance of the motor is as follows:

| Resonant Mode: | 2^{nd} at approximately 900 Hz |
|---|---|
| No-load Speed: | 600 RPM (10 Hz) |
| Stall Torque: | 0.5 N-m with the drive frequency increasing |
| | by approximately 10% at stall |
| Output Power: | 4 Watts peak |
| Electric Drive: | 130 Vac-pk (no DC offset) using standard |
| | linear drive electronics |
| Output Current: | 220 mA-pk at peak power with |
| | 56 degrees of phase shift |
| Motor Efficiency: | 46% |

One of the 12 bimorph motor beam elements 60, of which eleven are shown in FIG. 6, incorporates a strain sensing structure which is used for resonance and feedback monitoring by the prototype amplifier. This sensing structure and dynamic control circuitry within the amplifier is used since the resonance of the piezomotor changes as a function of both rotational speed and output loading. Both no-load speed and stall torque increase linearly with drive voltage, when driven at resonance. The ceramic, bimorph beams 60 can safely be driven up to 300 V peak-to-peak (0.6 kV/mm, electric field break-down), which should therefore double both the no-load speed and stall torque, and quadruple the power output when driven at 300 volts. The bimorph beams 60 are located within a mass element 62, which surrounds a driven shaft 64 and a roller clutch 66.

The present invention discloses generalized piezomotor drive electronics that efficiently operate at both electrical and mechanical resonance. The power efficiency of the Resonant Regenerative Switching Amplifier has been calculated to be greater than 80% when driving a 1 μF piezoelectric load with a 500 V peak-to-peak signal. The available output power should be greater than 20 watts continuously from DC to 2.0 kHz.

Although certain presently preferred embodiments of the present invention have been specifically described herein, it will be apparent to those skilled in the art to which the invention pertains that variations and modifications of the various embodiments shown and described herein may be made without departing from the spirit and scope of the invention. For example, numerical values are illustrative rather than limiting, as are references to specific integrated circuit technology. Accordingly, it is intended that the invention be limited only to the extent required by the appended claims and the applicable rules of law.

1. A piezoelectric drive amplifier circuit comprising:
a first capacitor and a second capacitor connected in series through a transformer comprising a first and second inductor;
a third inductor connected in series between the first and second capacitors; and
at least one switch for connecting the first and second capacitors and a switch controller for controlling the at least one switch such that energy is transferred between the first and second capacitors so that the circuit is operated at near its electrical resonance for the circuit.

2. The piezoelectric drive amplifier circuit of claim 1, wherein: the first capacitor is a piezoeletric element and the second capacitor is a storage capacitor.

3. The piezoelectric drive amplifier circuit of claim 1, wherein:
the at least one switch includes a first switch connected in series to the first inductor, a second switch connected in series to the second inductor, and a third switch connected in series to the third inductor.

4. The piezoelectric drive amplifier circuit of claim 3, further comprising:
an error amplifier connected in parallel between the first capacitor and the second capacitor.

5. The piezoelectric drive amplifier circuit of claim 4, wherein: the error amplifier comprises an input for receiving an input signal, said error amplifier initiating a transfer of energy between the first and second capacitor in accordance with the input signal.

6. A piezoelectric drive amplifier circuit for converting electrical energy to mechanical energy comprising:
a first and second capacitor capable of storing energy; and
at least one switch for connecting the first and second capacitors and a switch controller for controlling the at least one switch such that energy is transferred between the first and second capacitors so that the circuit is operated at near its electrical resonance for the circuit.

7. The piezoelectric drive amplifier circuit for converting electrical energy to mechanical energy of claim 6, further comprising:
an error amplifier is connected to a switch controller and initiates the transfer of energy between the first capacitor and the second capacitor.

8. The piezoelectric drive amplifier circuit of claim 7, wherein:
the error amplifier comprises an input for receiving an input signal, said error amplifier initiating a transfer of energy between the first and second capacitor in accordance with the input signal.

9. The piezoelectric drive amplifier circuit for converting electrical energy to mechanical energy of claim 7, wherein:
the first capacitor is a piezoelectric element and the second capacitor is a storage capacitor, and the error amplifier initiates the transfer of energy from the first capacitor to the second capacitor when (V_{cx}-V_{IN})>αΔV, where V_{cx} is the voltage of the first capacitor, V_{IN} is the voltage of an input signal at the error amplifier; ΔV is a voltage step size, and Δ is a constant between 0 and 1.

10. The piezoelectric drive amplifier circuit for converting electrical energy to mechanical energy of claim 7, wherein:
the first capacitor is a piezoelectric element and the second capacitor is a storage capacitor, and the error amplifier initiates the transfer of energy from the second capacitor to the first capacitor when (V_{IN}-V_{cx})>αΔV, where V_{cx} is the voltage of the second capacitor, V_{IN} is the voltage of an input signal at the error amplifier; ΔV is a voltage step size, and α is a constant between 0 and 1.

11. The piezoelectric drive amplifier circuit for converting electrical energy to mechanical energy of claim 7, further comprising:
a first switch, a second switch and a third switch connected in parallel between the first and second capacitor.

12. The piezoelectric drive amplifier circuit for converting electrical energy to mechanical energy of claim 11, wherein:
the first switch is closed to initiate the energy transfer from the first capacitor to the second capacitor.

13. The piezoelectric drive amplifier circuit for converting electrical energy to mechanical energy of claim 11, wherein:
the first and second switches are closed to initiate the energy transfer from the second capacitor to the first capacitor.

14. The piezoelectric drive amplifier circuit for converting electrical energy to mechanical energy of claim 11, wherein:
an inductor is connected in series between the first and second capacitors.

15. The piezoelectric drive amplifier circuit for converting electrical energy to mechanical energy of claim 7, wherein:
the at least one switch is a field effect transistor switch.

16. The piezoelectric drive amplifier circuit for converting electrical energy to mechanical energy of claim 7, wherein:
the at least one switch is metal oxide semiconductor field effect transistor switch.

17. A method of converting electrical energy to mechanical energy using a piezoelectric drive amplifier comprising the steps of:
inputting a signal with a frequency into an error amplifier;
initiating a transfer of energy between a first and second capacitor, wherein the first capacitor is a piezo electric element and the second capacitor is a storage capacitor; and
converting the energy in the first capacitor into mechanical energy.

18. The method of converting electrical energy to mechanical energy using a piezoelectric drive amplifier of claim 17, further comprising the steps of:
initiating the transfer of energy from the first capacitor to the second capacitor when (V_{cx}-V_{IN})>αΔV, where V_{cx} is the voltage of the second capacitor, V_{IN} is the voltage of an input signal at the error amplifier; ΔV is a voltage step size, and α is a constant between 0 and 1.

19. The method of converting electrical energy to mechanical energy using a piezoelectric drive amplifier of claim 17, further comprising the steps of:
initiating the transfer of energy from the second capacitor to the first capacitor when (V_{IN}-V_{cx})>αΔV, where V_{cx} is the voltage of the second capacitor, V_{IN} is the voltage of an input signal at the error amplifier; ΔV is a voltage step size, and Δ is a constant between 0 and 1.

20. The method of converting electrical energy to mechanical energy using a piezoelectric drive amplifier of claim 17, further comprising the steps of:
adding energy to the second capacitor to compensate for energy lost due to mechanical work in the piezoelectric element.
